(19) United States
(12) Patent Application Publication
(10) Pub. No.: US 2019/0131162 A1
(43) Pub. Date: May 2, 2019

(54) NON-ELECTROSTATIC CHUCK HEATER

(71) Applicants: SURANJAN DABARE, COLOMBO (LK); LEO PASION, SANTA ROSA (PH); ROMMEL MONTES, CALGARY (CA)

(72) Inventors: SURANJAN DABARE, COLOMBO (LK); LEO PASION, SANTA ROSA (PH); ROMMEL MONTES, CALGARY (CA)

(21) Appl. No.: 15/800,507

(22) Filed: Nov. 1, 2017

(51) Int. Cl. H01L 21/687; H01L 21/683; H01L 21/68; H01L 21/67; H01L 21/02

(52) U.S. Cl. CPC H01L 21/6875; H01L 21/6833; H01L 21/682; H02N 13/00; H01L 21/67109; H01L 21/02008; H01L 21/67017

(57) ABSTRACT

An apparatus for supporting a semiconductor wafer comprises a first disk receiving a gas in a central portion of the first disk. The gas is distributed within the first disk. A second disk is coupled above the first disk. The second disk comprises a heater and receives the gas from the first disk. A third disk is coupled above the second disk. The third disk receives the gas through the second disk. An upper surface of the third disk comprises a plurality of hemispheres protruding above the surface of the third disk. The plurality of hemispheres support the semiconductor wafer. The gas passes through the third disk and heats the wafer. Heat is conducted from the plurality of hemispheres to the wafer. The gas is heated as it passes from the second disk to the third disk the wafer is heated by contact with the heated gas.

### FIELD OF THE INVENTION

The present invention relates to the field of semiconductor manufacturing, more specifically to the use of a heated chuck to hold wafers in place during manufacture and processing.

### BACKGROUND OF THE INVENTION

Electrostatic chucks (ESC) are used in a variety of semiconductor processes to hold the wafer during processing. ESCs employ a platen with integral electrodes which are biased with high voltage to establish an electrostatic holding force between the platen and wafer. ESCs also include heating or cooling elements to control the temperature of a wafer together with systems to control the heating and cooling curves of the wafer. Current ESC solutions are characterized by the high contact area that the platen makes with the wafer itself.

Current ESC solutions provide an expensive solution and suffer from a number of drawbacks. One drawback is that the chucking of the wafer may be non-uniform that may lead to an increase in backside defects of the wafer. The increased number of backside defects in turn also increased the number of front side defects. Another drawback is that due to the direct contact of the ESC to the wafer the backside of the wafer also tends to get scratched and metal contamination may occur. These problems are also exasperated by the lack of adequate solutions to heat and cool the temperature of the wafer. All of these lead to a decrease in semiconductor manufacturing yield and drive up the costs of semiconductor devices.

There exists a need for an ESC solution that provides an economical way of securing a wafer without increasing defects and of providing improved heating and cooling curves.

Other aspects and features of the present invention will become apparent to those ordinarily skilled in the art upon review of the following description of specific embodiments of the invention in conjunction with the accompanying figures.

### SUMMARY OF THE INVENTION

It is an object of the present invention to address limitations in the prior art relating to field of semiconductor manufacturing, more specifically to the use of a heated chuck to hold wafers in place during manufacture and processing

An aspect of embodiments of the invention includes an apparatus for supporting a semiconductor wafer comprising a first disk receiving a gas in a central portion of the first disk. The gas being distributed within the first disk. A second disk coupled above the first disk. The second disk comprising a heater. The second disk receiving the gas from the first disk. The gas being heated within the second disk to produce a heated gas. A third disk coupled above the second disk. The third disk receiving the heated gas through the second disk. An upper surface of the third disk comprising a plurality of hemispheres protruding above the surface of the third disk. The plurality of hemispheres supporting the semiconductor wafer. The heated gas passing through the third disk and heating the wafer.

In further embodiments, heat is conducted from the plurality of hemispheres to the wafer. In other embodiments, the wafer is heated by convection from the heated gas.

In other embodiments, the first disk comprises a sprinkler structure positioned in the center of the first disk and a reservoir formed by an outer portion of the disk. The sprinkler structure receives the gas and distributes the gas to a reservoir formed in an outer portion of the first disk.

In further embodiments, the apparatus comprises a reservoir formed between the second disk and the third disk. The heated gas passes through the reservoir as it passes from the second disk to the third disk.

In other embodiments, each of the plurality of bumps comprises a hemisphere and a post. The post of each of the plurality of bumps being received by a hole formed in the upper surface of the third disk.

In other embodiments, each of the plurality of bumps is comprised of sapphire.

In further embodiments, the third disk receives the heated gas through the second disk vis a first plurality of holes formed through the second disk. The heated gas passes through the third disk through a second plurality of holes formed through the third disk. The first plurality of holes is offset from the second plurality of holes.

In another embodiment, the diameter of the first plurality of holes is different from the diameter of the second plurality of holes.

In another embodiment, each of the second plurality of holes comprises an upper portion and a lower portion. The diameter of the upper portion being greater than the diameter of the second portion.

In some embodiments, the heater comprises a coil contained within the second disk. The coil having a substantially rectangular cross section.

In other embodiments, the coil comprises a first portion and a second portion. the first portion positioned in a central portion of the second disk. The second portion positioned in an outer portion of the second disk. In other embodiments, the apparatus further comprises a cooler.

In further embodiments, the third disk comprises a plurality of wafer guards. The plurality of wafer guards blocking a lateral movement of the wafer when the wafer is positioned on the third disk.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 depicts an overall view of the non esc chuck pedestal according to an embodiment of the invention;

FIG. 2 depicts a diagram illustrating the flow of heating gas through the layers of the pedestal;

FIG. 3 depicts an overall view of the top surface of the pedestal illustrating the placement and construction of the bumps;

FIG. 4 illustrates the third layer of the pedestal;

FIG. 5 illustrates the second layer of the pedestal;

FIG. 6 depicts a planar view of the heater coil according to an embodiment of the invention;

FIG. 7 depicts a cross section view of the heater coil according to an embodiment of the invention;

FIG. 8 illustrates the first layer of the pedestal;

FIG. 9 illustrates a gas sprinkler structure in the center or the first layer of the pedestal;

FIG. 10 illustrates a planar view of gas sprinkler structure;

### DETAILED DESCRIPTION

Embodiments of the present invention are directed to providing an improved electrostatic chuck for semiconductor wafer processing and more particularly to a non-electrostatic chuck including an improved backside gas distribution heating solution. One novel feature provides an improved pedestal design that limits the contact area between the platen and a wafer. Another novel feature is the use of a uniform backside gas distribution system. A third novel feature is the use of a heating coil with a square cross section. Embodiments of the invention may help to reduce capital investment as well as maintenance costs.

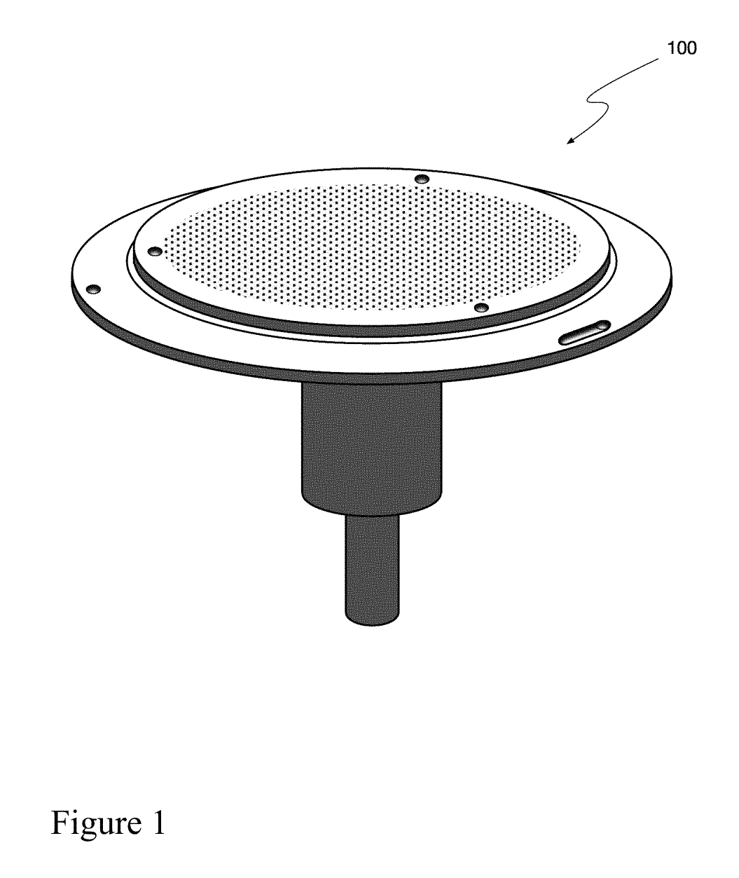

Referring to FIG. 1, a first major aspect of embodiments of the invention includes an improved pedestal 100 design to reduce the contact area between the pedestal platen and a wafer using a pattern of small, ball shaped, bumps. The wafer is not secured in place but only held by gravity and the friction between the backside of the wafer and the top of the bumps.

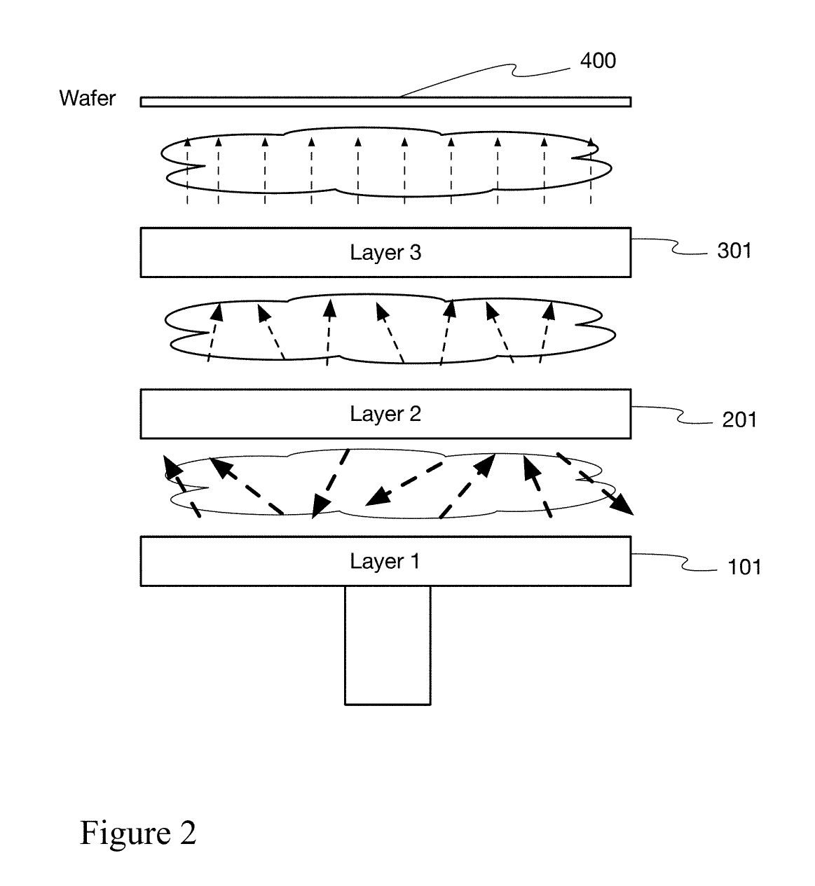

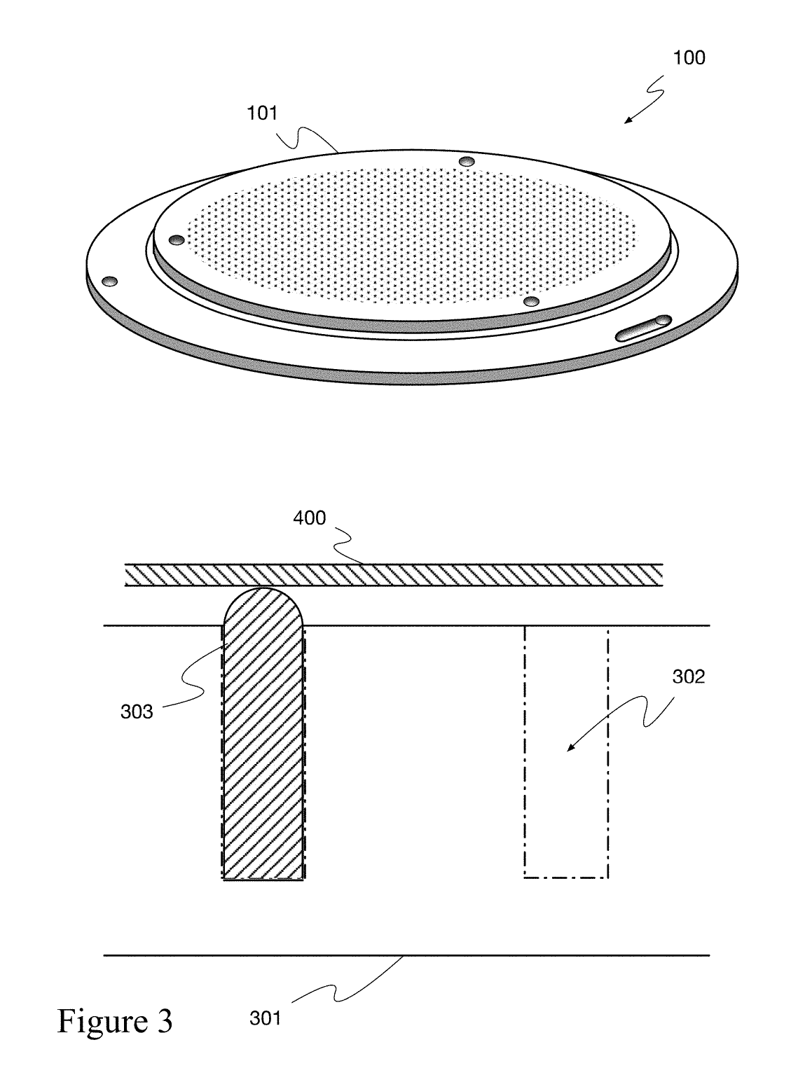

Referring to FIG. 2, In an exemplary embodiment the pedestal comprises three layers; from bottom to top, layer one 101, two 201, and three 301. The top, or third, layer supports the wafer 400 and is covered with a pattern of small, ball shaped, bumps. The layer is manufactured using a material such as stainless steel. Referring to FIG. 3, a pattern of holes 302 is formed in the top surface of this layer 101, with each hole 302 of a diameter and depth to accept a bump 303. Preferably, the holes 302 are formed substantially equidistant from each other over the surface and are positioned to optimize uniform heat transfer from the bumps 303 to the supported wafer 400. The holes 302 are typically formed by drilling and in an exemplary embodiment, each hole 302 is 0.5 mm deep and 0.3 mm in diameter. The number of holes 302 depends on a number of factors including the size of the wafer supported and the ability to form the holes but in exemplary embodiments, 150 to 200 holes may be formed to support a 300 cm wafer.

Each bump 303, which preferably takes the form of a post with a hemispheric top is inserted into each of the similarly sized hole 302 formed in the upper surface of the top pedestal layer 101. The post 303 may be press fitted into place. In an exemplary embodiment, each bump 303 is made of sapphire though ruby and other materials may also be used. The post 303 may be 0.3 mm in diameter and 0.5 mm long. The hemispheric top may be 0.15 mm in radius and protrude above the surface of the top pedestal 101 by 0.15 mm. In use, the wafer is supported on the tops of the hemispheric bumps 303. The hemispheric shape limits the contact surface between the pedestal 100 and the wafer 400 while presenting a smooth surface to minimize scratches. Reducing the contact area aids in minimizing the defects on the silicon wafer back side, reduces metal contamination, reduces backside scratches, and reduces the number front defects coming due to backside defects. The improved design also increases the efficiency of conduction heat transfer going upwards to the silicon backside and distributes the airflow more uniformly.

A second major aspect of embodiments of the invention includes the use of backside gas technology with a uniform gas distribution to control the wafer temperature, increase the temperature ramp rate of the wafer and improve the heating quality. The pedestal 100 uses a three-layer distribution to distribute heated gas from the bottom of the pedestal, up through the layers in proximity to a heating element, finally heating the backside of the wafer. The three layers are mounted together using screws, bolts or other means as known in the art. Heating is done using both convection and conduction heat transfer. Heat conduction happens where the pedestal 100 contacts the wafer 400 at the bumps 303. Heat convection happens with heat radiated from the heated gas. In use, the gas enters the pedestal and moves upwards through the three layers. The distribution of the gas in the three layers products a stable backside pressure.

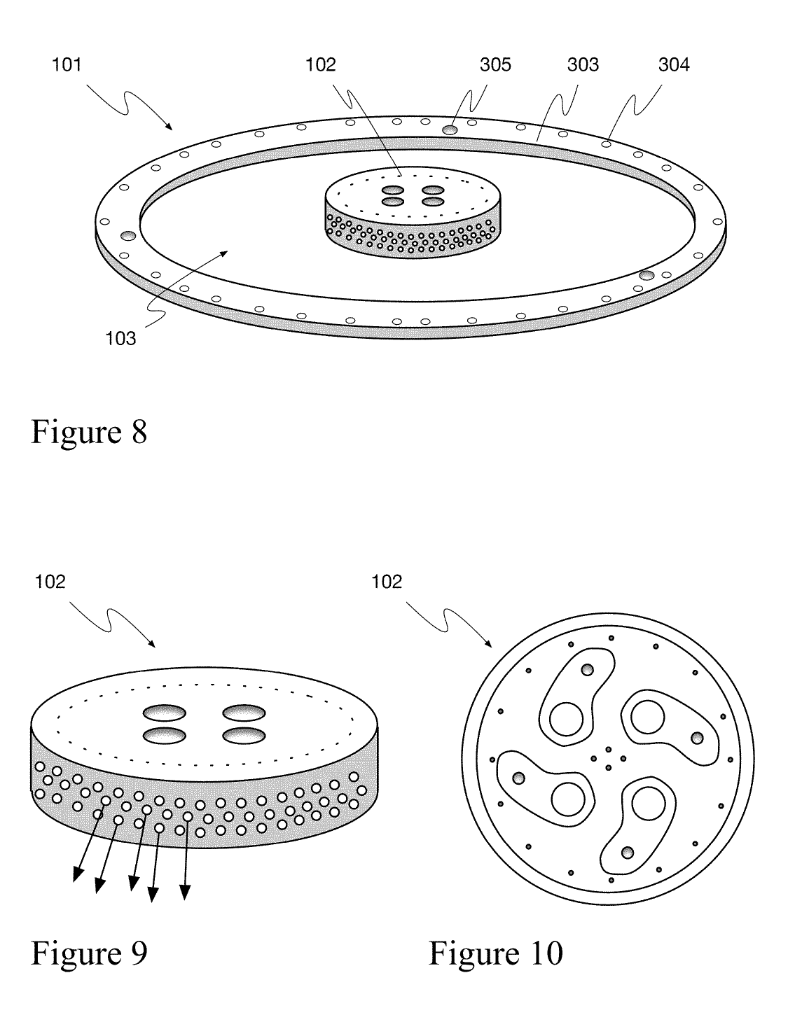

Referring to FIG. 8, at the lowest, first layer 101 gas enters the first layer through a gas inlet at room temperature. In a preferred embodiment, the gas inlet is part of a sprinkler 102 is in the center of the pedestal 100, but may also enter from other directions. The gas is typically argon, which is standard in the industry, but other suitable gases may be used. The first layer 101 serves the purpose of defining the movement of the gas from the center towards the outer areas of the layer 101. The gas enters up through the center of the layer which comprises a gas sprinkler structure 102 in the center and an open gas reservoir 103 surrounding the sprinkler within the first layer 101. The sprinkler 102, depicted in perspective and plan views in FIGS. 9 and 10, serves as a blocking plate to reduce the pressure and uniformly redistribute the gas at the first layer distribution reservoir 103. The reservoir 103 serves to balance the heating of the gas uniformly. The first layer 101 includes mounting features 304 to attach the first layer to the middle, second layer, or to both the second and third layer. A cooling coil may also be included in the pedestal. In an exemplary embodiment, a cooling coil enters the first layer 101 through the center and is coupled to a cooling plate in the center of the first layer to provide cooling. The cross section of the cooling coil may be square, oblong, oval, or round. The coolant is a liquid and the cooling plate is typically made of OFE (oxygen-free electrolytic) copper though SST may also be used.

Referring to FIG. 5, the middle, second layer 201 serves to change the angle of the gas. As gas leaves the first layer 101, it is directed in random directions. While passing through the holes in the second layer 201, the gas is directed towards a second reservoir formed between the second 201 and third 301 layers, in an upwards direction. The gas is further distributed and passes up to the top, third layer 301 through small holes 303. Holes for the gas are placed to avoid areas that contain the heating coil 207 208. The gas holes 203 must be small enough to not change the velocity of the gas. In a preferred embodiment, each hole 203 is nominally 1 mm in diameter.

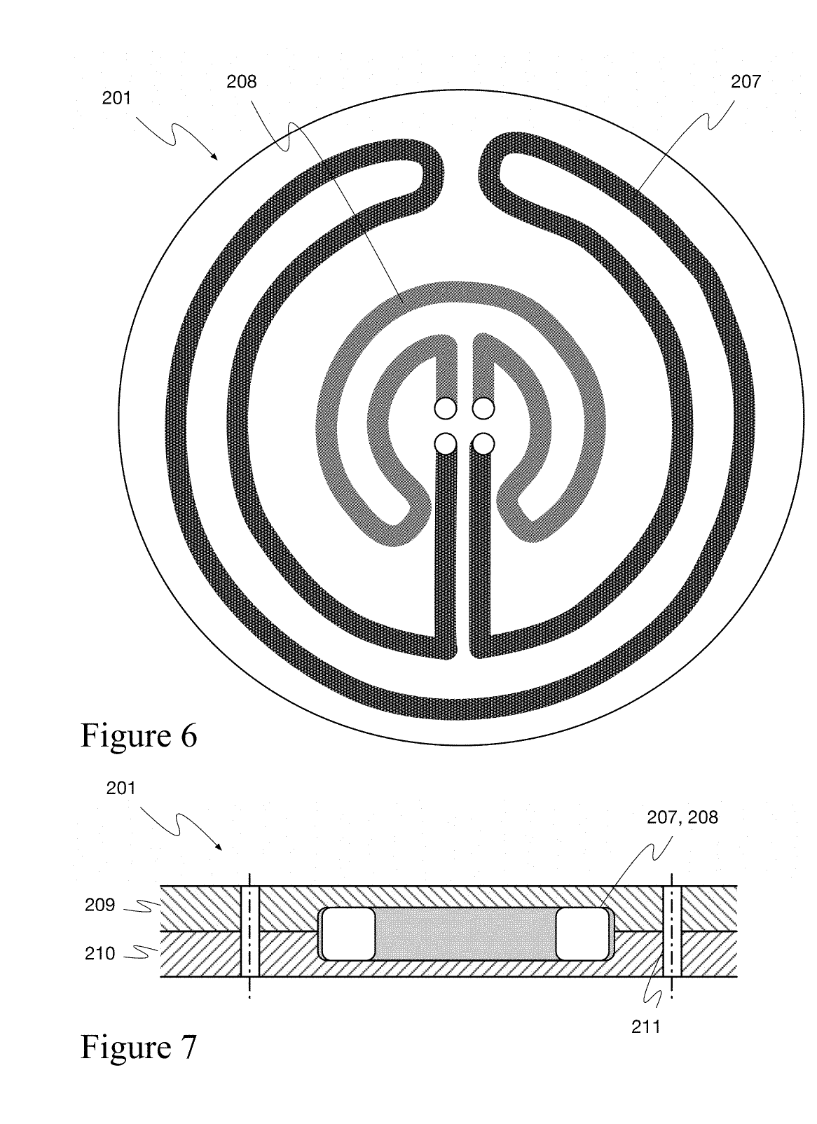

The second layer 201 also comprises a heating coil 207 208 or element to increase the temperature of the pedestal 100. This causes the gas to be heated. As the heated gas moves upwards through the pedestal 100, from first 101, to second 201, to third layer 301, it helps in increasing the temperature ramp rate. The heating coil 207 208 enters the second layer 201, typically through the center of the layer and is routed to evenly cover the area of the layer. Referring to FIG. 7, in an exemplary embodiment, the heater comprises a coil that is rectangular in cross section which allows for more efficient heat transfer from the heating coil to the surrounding pedestal and is disposed in a predetermined pattern, such as that depicted in FIG. 6 for example. Round or oval cross sections may also be used though the heating efficiency may be reduced. The heating coil may be divided into two independent sections to form a dual zone heating element, one zone 208 in the center of the layer, and another zone 207 towards the outside of the layer. The current through the two coil sections may be controlled to increase the heating of the pedestal. The second layer may be formed from an upper 209 and lower portion 210 that are held together with the heating coil sandwiched between. Mounting features 211 are then included to hold the upper and lower portions together.

Alignment pins 205 are included to align the three layers and mounting holes 204 are distributed around the perimeter. Alignment pins 205 may be placed in the top and bottom of the second layer with corresponding alignment holes to receive them in the first and third layers. Alternatively, the alignment pins may and alignment holes may be reversed. A second gas reservoir is formed between the second and third layers to allow the gas to circulate and redistribute before passing through the holes in the third layer.

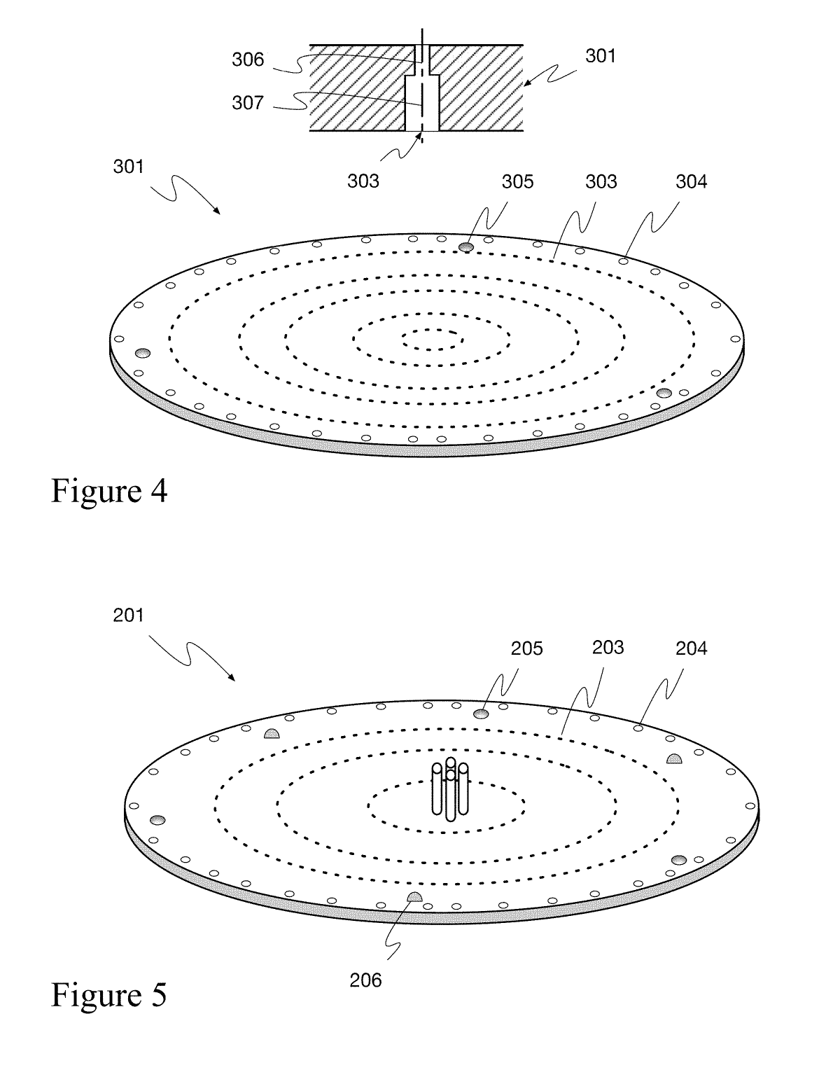

Referring to FIG. 4, the top, third layer 301, also comprises a number of holes 303 distributed over its surface and serves the purpose of producing a controlled and directional gas flow, uniformly over the backside of the wafer. The holes 303 in the third layer are offset from the holes 203 in the second layer. In a preferred embodiment, the holes 303 comprise an upper portion 306 and a lower portion 307, the upper portion 306 being closer to the top surface of the third layer 301, closer to the wafer 400. In an exemplary embodiment, the lower portion 307 of the holes 303 are nominally 2.4 mm in diameter, and the upper portion 306 of the holes 303 are nominally 0.8 mm in diameter. The third layer 301 presents a smooth top surface with a pattern of bumps 303 protruding from the top surface as described above to support the wafer. The heated bumps 303 transfer heat to the backside of the wafer 400 through conduction where the bumps 303 contact the wafer 400. After passing through the third layer 301, the heated gas will be directed straight, perpendicular towards the backside of the wafer 400. Together with conduction heating, the heated gas heats the wafer 400 through convection. Wafer guards, preferably three, may be distributed around the perimeter of the top of the third layer to serve as a wafer guard. Wafer guards serve to protect the wafer from sudden, lateral sliding of the wafer. The third layer 301 includes mounting features 305 to attach the third layer to the middle, second layer 201, or to both the first 101 and second layer 201.

Preferably the pedestal 100 is made of stainless steel though other materials may also be used.

The ensuing description provides representative embodiment(s) only, and is not intended to limit the scope, applicability or configuration of the disclosure. Rather, the ensuing description of the embodiment(s) will provide those skilled in the art with an enabling description for implementing an embodiment or embodiments of the invention. It being understood that various changes can be made in the function and arrangement of elements without departing from the spirit and scope as set forth in the appended claims. Accordingly, an embodiment is an example or implementation of the inventions and not the sole implementation. Various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention can also be implemented in a single embodiment or any combination of embodiments.

Reference in the specification to “one embodiment”, “an embodiment”, “some embodiments” or “other embodiments” means that a particular feature, structure, or characteristic described in connection with the embodiments is included in at least one embodiment, but not necessarily all embodiments, of the inventions. The phraseology and terminology employed herein is not to be construed as limiting but is for descriptive purpose only. It is to be understood that where the claims or specification refer to “a” or “an” element, such reference is not to be construed as there being only one of that element. It is to be understood that where the specification states that a component feature, structure, or characteristic “may”, “might”, “can” or “could” be included, that particular component, feature, structure, or characteristic is not required to be included.

Reference to terms such as “left”, “right”, “top”, “bottom”, “front” and “back” are intended for use in respect to the orientation of the particular feature, structure, or element within the Figures depicting embodiments of the invention. It would be evident that such directional terminology with respect to the actual use of a device has no specific meaning as the device can be employed in a multiplicity of orientations by the user or users.

Reference to terms “including”, “comprising”, “consisting” and grammatical variants thereof do not preclude the addition of one or more components, features, steps, integers or groups thereof and that the terms are not to be construed as specifying components, features, steps or integers. Likewise, the phrase “consisting essentially of”, and grammatical variants thereof, when used herein is not to be construed as excluding additional components, steps, features integers or groups thereof but rather that the additional features, integers, steps, components or groups thereof do not materially alter the basic and novel characteristics of the claimed composition, device or method. If the specification or claims refer to “an additional” element, that does not preclude there being more than one of the additional element.

What is claimed is:

1. An apparatus for supporting a semiconductor wafer, the apparatus comprising:
a first disk receiving a gas in a central portion of the first disk, the gas being distributed within the first disk;
a second disk coupled above the first disk, the second disk comprising a heater, the second disk receiving the gas from the first disk, the gas being heated within the second disk to produce a heated gas; and
a third disk coupled above the second disk, the third disk receiving the heated gas through the second disk, an upper surface of the third disk comprising a plurality of hemispheres protruding above the surface of the third disk, the plurality of hemispheres supporting the semiconductor wafer, the heated gas passing through the third disk and heating the wafer.

2. The apparatus of claim 1, wherein
heat is conducted from the plurality of hemispheres to the wafer.

3. The apparatus of claim 1, wherein
the wafer is heated by convection from the heated gas.

4. The apparatus of claim 1, wherein
the first disk comprises a sprinkler structure positioned in the center of the first disk and a reservoir formed by an outer portion of the disk, the sprinkler structure receiving the gas and distributing the gas to a reservoir formed in an outer portion of the first disk.

5. The apparatus of claim 1, further comprising
a reservoir formed between the second disk and the third disk, the heated gas passing through the reservoir as it passes from the second disk to the third disk.

6. The apparatus of claim 1, wherein
each of the plurality of bumps comprises a hemisphere and a post, the post of each of the plurality of bumps being received by a hole formed in the upper surface of the third disk.

7. The apparatus of claim 6, wherein
each of the plurality of bumps is comprised of sapphire.

8. The apparatus of claim 1, wherein
the third disk receives the heated gas through the second disk vis a first plurality of holes formed through the second disk, the heated gas passing through the third disk through a second plurality of holes formed through the third disk, the first plurality of holes offset from the second plurality of holes;

9. The apparatus of claim 8, wherein
the diameter of the first plurality of holes is different from the diameter of the second plurality of holes.

10. The apparatus of claim 8, wherein
each of the second plurality of holes comprises an upper portion and a lower portion, the diameter of the upper portion being greater than the diameter of the second portion.

11. The apparatus of claim 1, wherein
the heater comprises a coil contained within the second disk, the coil having a substantially rectangular cross section.

12. The apparatus of claim 11, wherein
the coil comprises a first portion and a second portion, the first portion positioned in a central portion of the second disk, the second portion positioned in an outer portion of the second disk.

13. The apparatus of claim 1, further comprising
a cooler.

14. The apparatus of claim 1, wherein
the third disk further comprises a plurality of wafer guards, the plurality of wafer guards blocking a lateral movement of the wafer when the wafer is positioned on the third disk.
